(19) United States
(12) Patent Application Publication
(10) Pub. No.: US 2016/0013288 A1
(43) Pub. Date: Jan. 14, 2016

(54) METHOD OF FORMING A METAL GATE STRUCTURE

(71) Applicant: UNITED MICROELECTRONICS CORP., Hsin-Chu City (TW)

(72) Inventors: Chi-Piao Cheng, New Taipei City (TW); Kuan-Ting Wu, Yunlin County (TW); Po-Ting Chen, Tainan City (TW); Chih-Hsien Chang, Yunlin County (TW)

(21) Appl. No.: 14/326,476

(22) Filed: Jul. 9, 2014

(51) Int. Cl. H01L 29/49; H01L 21/28; H01L 21/321; H01L 21/311; H01L 29/66; H01L 21/285

(52) U.S. Cl. CPC H01L 29/4966; H01L 29/66568; H01L 21/28568; H01L 21/321; H01L 21/31105; H01L 21/28088

(57) ABSTRACT

The present invention provides a method of forming a metal gate structure. A substrate and a dielectric layer with a trench are provided. Next, a work function metal (WFM) layer is formed in the trench, following by performing an oxidation process under a vacuum condition to oxidize a part of the WFM layer to form an oxidized WFM layer. Thereafter, a conductive layer is formed on the oxidized WFM layer to complete fill the trench.

### BACKGROUND OF THE INVENTION

1. Field of the Invention

The present invention is related to a method of forming a metal gate structure, and more particularly, to a method of forming a metal gate structure with an oxidation process.

2. Description of the Prior Art

Poly-silicon is conventionally used as a gate electrode in semiconductor devices, such as the metal-oxide-semiconductor (MOS). However, with a trend toward scaling down the size of semiconductor devices, the conventional poly-silicon gate has faced problems such as inferior performance due to boron penetration and unavoidable depletion effect which increases equivalent thickness of the gate dielectric layer, reduces gate capacitance, and worsens a driving force of the devices. Therefore, work function metals are used to replace the conventional poly-silicon gate to be the control electrode that is suitable for use as the high-k gate dielectric layer.

In a complementary metal-oxide semiconductor (CMOS) device, one of the dual work function metal gates is used in an NMOS device and the other one is alternatively used in a PMOS device. It is well-known that compatibility and process control for the dual metal gate are more complicated, meanwhile thickness and composition controls for materials used in the dual metal gate method are more precise. The conventional dual metal gate methods are categorized into gate first processes and gate last processes. In a conventional dual metal gate method applied with the gate first process, the annealing process for forming the source/drain ultra-shallow junction, and the silicide process are performed after forming the metal gate. In the conventional gate last process, a sacrifice gate or a replacement gate is provided and followed by performing processes used to construct a normal MOS transistor. Then, the sacrificial/replacement gate is removed to form a gate trench. Consequently, the gate trench is filled with metals according to the different electrical requirements. However, because of the complicated steps of the gate last processes, the manufacturers are devoted to simplifying the manufacturing process.

In the gate first process or the gate last process, the metal gate of the PMOS or the NMOS may include a plurality of metal layers. The materials of the metal layers always affect the work function of the NMOS or the PMOS, therefore affect the performance of the product. Thus, the manufacturers are searching for new manufacturing method to obtain a MOS with better work function performance.

### SUMMARY OF THE INVENTION

The present invention therefore provides a method of forming a metal gates structure, which exhibits good electrical performance.

According to one embodiment of the present invention, the method of forming a metal gate structure has the following steps. A substrate and a dielectric layer with a trench are provided. Next, a work function metal (WFM) layer is formed in the trench, following by performing an oxidation process under a vacuum condition to oxidize a part of the WFM layer to form an oxidized WFM layer. Thereafter, a conductive layer is formed on the oxidized WFM layer to complete fill the trench.

The present invention eliminates the needs to transfer the wafer out from the apparatus to the oxidized WFM layer and one only deposition apparatus is needed to conduct all the metal gate deposition processes (in-situ deposition and oxidation). Moreover, since the oxidation process is performed by supplying oxygen containing gas in the chamber, instead of the atmosphere in conventional arts, and it can be carried out with an annealing process, the quality of the oxidized WFM layer and the throughput of the process can be upgraded.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 show a schematic diagram of the deposition apparatus and deposition chamber according to one embodiment of the present invention.

FIG. 3 shows a flow chart of the method of forming a metal gate structure according to one embodiment of the present invention.

FIG. 4 to FIG. 10 show schematic diagrams of the method of forming a metal gate structure according to one embodiment of the present invention.

### DETAILED DESCRIPTION

To provide a better understanding of the presented invention, preferred embodiments will be made in detail. The preferred embodiments of the present invention are illustrated in the accompanying drawings with numbered elements.

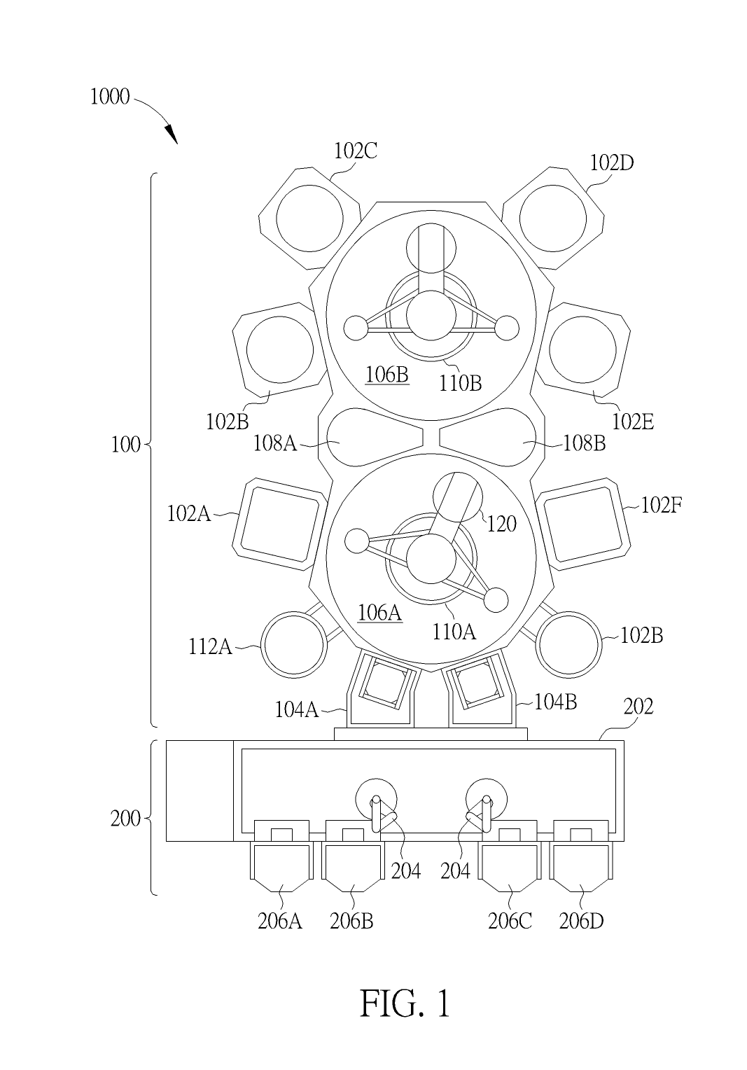

Please refer to FIG. 1, which shows a schematic diagram of the deposition apparatus according to one embodiment of the present invention. Available example of the deposition apparatus includes ENDURA®, CENTURA®, and PRODUCER®, which are commercially available from Applied Material, Inc. It is contemplated that the methods described herein may be practiced in other tools having the requisite process chambers coupled thereto, including those available from other manufacturers.

As shown in FIG. 1, the deposition apparatus 1000 includes a vacuum-tight processing platform 100 and a factory interface 200. The platform 100 comprises a plurality of processing chambers 102A, 102B, 102C, 102D, 102E, 102F, load-lock chambers 104A, 104B, transfer chambers 106A, 106B, service chambers 112A, 112B and temporary chambers 108A, 108B. The factory interface 200 is coupled to the transfer chamber 106A by the load lock chambers 104A and 104B.

In one embodiment, the factory interface 200 comprises at least one docking station 202, at least one factory interface robot 204 to facilitate transfer of wafer or object. The docking station 202 is configured to accept one or more front opening unified pod (FOUP). Four FOUPS 204A, 204B, 204C and 204D are shown in the embodiment of FIG. 1. The factory interface robot 204 is configured to transfer the substrate 120 from the factory interface 200 to the processing platform 100 for processing through the loadlock chambers 104A, 104B.

Each of the loadlock chambers 104A, 104B have a first port coupled to the factory interface 200 and a second port coupled to the transfer chamber 106A. The loadlock chamber 104A, 104B are coupled to a pressure control system (not shown) which pumps down and vents the chambers 104A, 104B to facilitate passing the wafer between the vacuum environment of the transfer chamber 106A and the substantially ambient (e.g., atmospheric) environment of the factory interface 200. Therefore, the platform 100 of the deposition apparatus 1000 can be maintained in an ultrahigh vacuum environment.

A robot arm 110A disposed in the transfer chamber 106A can transfer the substrate 120 between the load lock chambers 104A, 104B, the processing chambers 102A, 102F, the temporary chambers 108A, 108B, and the service chambers 112A, 112B. A robot arm 110B disposed in the transfer chamber 106B can transfer the substrate 120 between the processing chambers 102B, 102C, 102D, 102E, and the temporary chambers 108A, 108B. The temporary chambers 108A, 108B are used to maintain ultrahigh vacuum conditions while allowing substrate 120 to be transferred between the transfer chamber 106A and the transfer chamber 106B within the platform 100. Each processing chamber 102A-102F may be configured to perform one of a number of substrate processing operations, such as cyclical layer deposition (including atomic layer deposition (ALD)), chemical vapor deposition (CVD), physical vapor deposition (PVD), pre-clean, de-gas, orientation and other substrate processes. The detailed description of the chambers will be shown in the following context. An optional service chamber 112A, 112B may be coupled to the transfer chamber 103. In one embodiment, optional service chambers 112A, 112B may be configured to perform other substrate processes, such as degassing, orientation, pre-cleaning process, cool down and the like, but is not limited thereto.

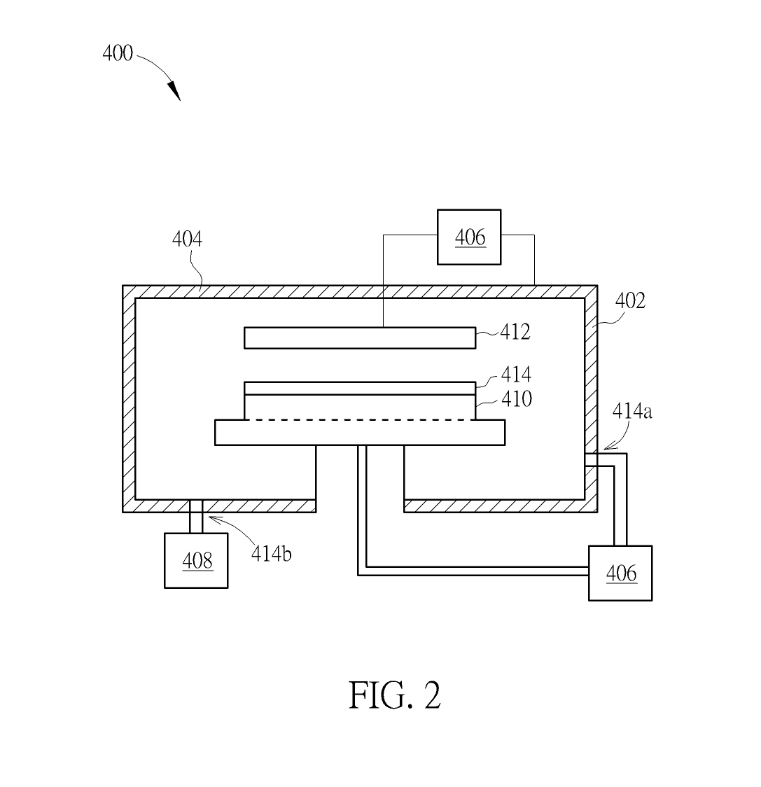

Please refer to FIG. 2, which shows a schematic diagram of the chamber in the deposition apparatus according to one embodiment of the present invention. It is understood that all the chambers, including the processing chambers 102A-102F and the service chambers 112A, 112B may have the similar structure as that in FIG. 2. As shown in FIG. 2, the chamber 400 includes a chamber body 402, a lid assembly 404, a gas source 406, a gas pump 408 and a pedestal 410. The chamber body 402 is enclosed by the lid assembly 404. A plurality of gas inlets 414a, 414b are disposed at the lid assembly 404 or a portion of the chamber body 402 for providing gas into/out the chamber 400, in which the gas inlet 414a is coupled to the gas source 406 for supplying processing gas while the gas inlet 414b is coupled to the gas pump 408 for maintaining a desired gas pressure or evacuating post-processing gases and by-products of the process from the chamber 400. The supporting pedestal 410 may include an embedded heater element (not shown) suitable for controlling the temperature of a substrate 414 supported thereon. In one embodiment, the gas source 406 can supply required gas to the pedestal 410. A target 412 is positioned above the substrate 414 and is comprised of a material to be deposited on the substrate 414. An electrode 416 is coupled to the target 412 to provide power for deposition.

Generally, in comparison with other chambers, the temporary chamber 108A, 108B does not perform deposition process so no deposition unit (for example, the target 412 or the deposition electrode 416) is installed herein. In some embodiment, the temporary chamber 108A, 108B can install the gas source 406 and/or a heater in the pedestal 410, so as to provide required gas or temperature.

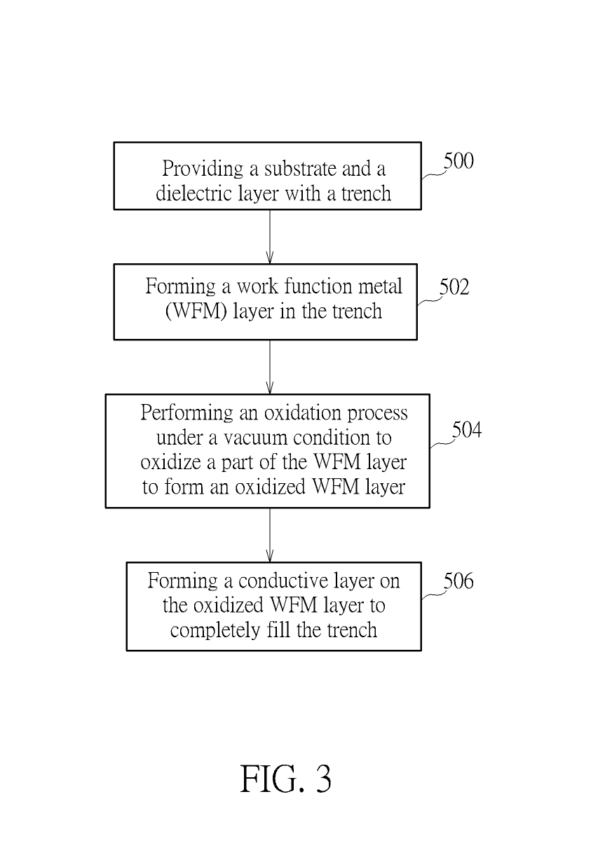

Please refer to FIG. 3, which shows a flow chart of the method of forming a metal gate structure according to one embodiment of the present invention. The method provided in the present invention includes the following steps:

Step 500: providing a substrate and a dielectric layer with a trench;

Step 502: forming a work function metal (WFM) layer in the trench;

Step 504: performing an oxidation process under a vacuum condition to oxidize a part of the WFM layer to form an oxidized WFM layer; and

Step 506: forming a conductive layer on the oxidized WFM layer to completely fill the trench.

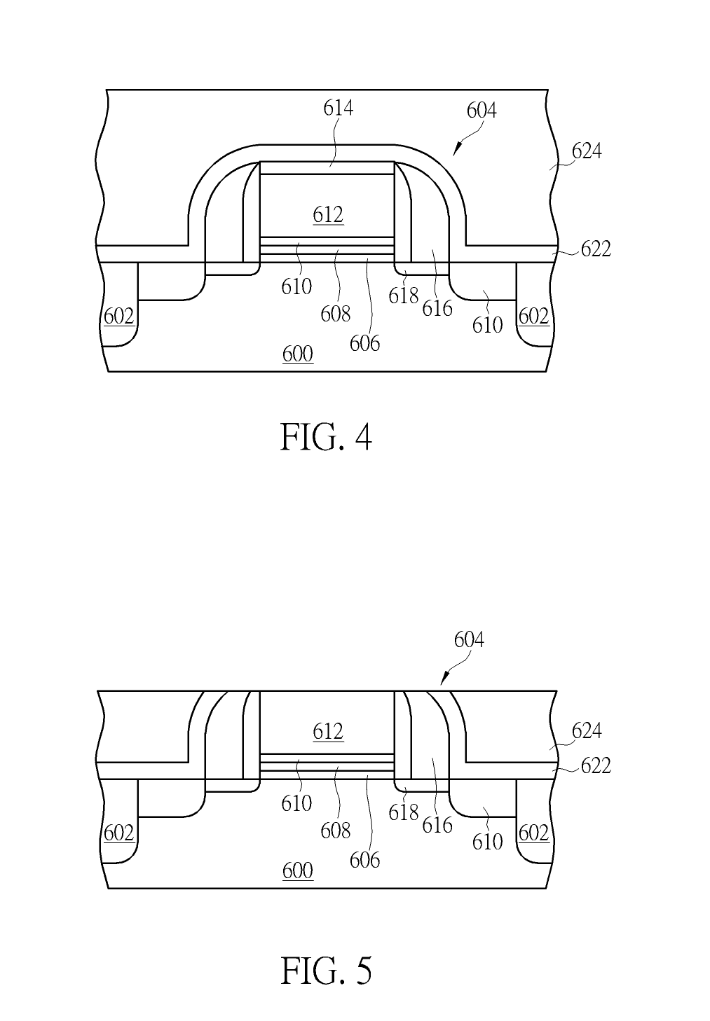

For the detail description, please refer to FIG. 4 to FIG. 10, which show schematic diagrams of the method of forming a metal gate structure according to one embodiment of the present invention. First, as shown in FIG. 4, a substrate 600 is provided, such as a silicon substrate, a silicon-containing substrate or a silicon-on-insulator (SOI) substrate. A plurality of shallow trench isolations (STI) 602 are disposed in the substrate 600. A transistor 604 is formed on the substrate 600 and is encompassed by the STI 602. The transistor 604 can be a P-type transistor or an N-type transistor, depending on different requirements. The following context will take the transistor 604 as an N-type transistor for example.

In one embodiment, the transistor 604 includes an interfacial layer 606, a gate dielectric layer 608, an etching stop layer 610, a sacrifice gate 612, a capping layer 614, a spacer 616, alight doped drain (LDD) 618 and a source/drain 620, for example. In one preferred embodiment of the present invention, the interfacial layer 606 includes SiO₂ which is formed by an oxidation process for example. The gate dielectric layer 608 is comprised of high-k material, for example, rare earth metal oxide or lanthanide oxide, such as hafnium oxide (HfO₂), hafnium silicon oxide (HfSiO₄), hafnium silicon oxynitride (HfSiON), aluminum oxide (Al₂O₃), lanthanum oxide (La₂O₃), lanthanum aluminum oxide (LaAlO), tantalum oxide (Ta₂O₅), zirconium oxide (ZrO₂), zirconium silicon oxide (ZrSiO₄), hafnium zirconium oxide (HfZrO), yttrium oxide (Yb₂O₃), yttrium silicon oxide (YbSiO), zirconium aluminate (ZrAlO), hafnium aluminate (HfAlO), aluminum nitride (AlN), titanium oxide (TiO₂), zirconium oxynitride (ZrON), hafnium oxynitride (HfON), zirconium silicon oxynitride (ZrSiON), hafnium silicon oxynitride (HfSiON), strontium bismuth tantalite (SrBi₂Ta₂O₉, SBT), lead zirconate titanate (PbZrₓTi₁₋ₓO₃, PZT) or barium strontium titanate (BaₓSr₁₋ₓTiO₃, BST), but is not limited thereto. The etching stop layer 610 includes metal or metal nitride, such as Ti, TiN, Ta, TaN, Ti/TiN, Ta/TaN or their combination. The sacrifice gate 612 comprises poly-silicon, amorphous silicon or germanium. The capping layer 614 is an optional layer including SiN or SiO₂. The spacer 616 can be a multilayered structure including high temperature oxide (HTO), SiN, SiO or SiN formed by hexachlorodisilane (Si₂Cl₆) (HCD-SiN). The LDD 618 and the source/drain 620 are formed by appropriate implant doping. In one embodiment, the interfacial layer 606 is about 10 angstroms, the gate dielectric layer 608 is about 20 angstroms, and the etching stop layer 610 is about 20 angstroms. After forming the transistor 604, a contact etch stop layer (CESL) 622 and an inter-layer dielectric (ILD) layer 624 are formed on the substrate 600 to cover the transistor 604.

As shown in FIG. 5, a planarization process, such as a chemical mechanical polish (CMP) process or an etching-back process or their combination is performed to remove a part of the ILD layer 624, a part of the CESL 622, a part of the spacer 616 and completely remove the capping layer 614, until a top surface of the sacrifice gate 612 is exposed.

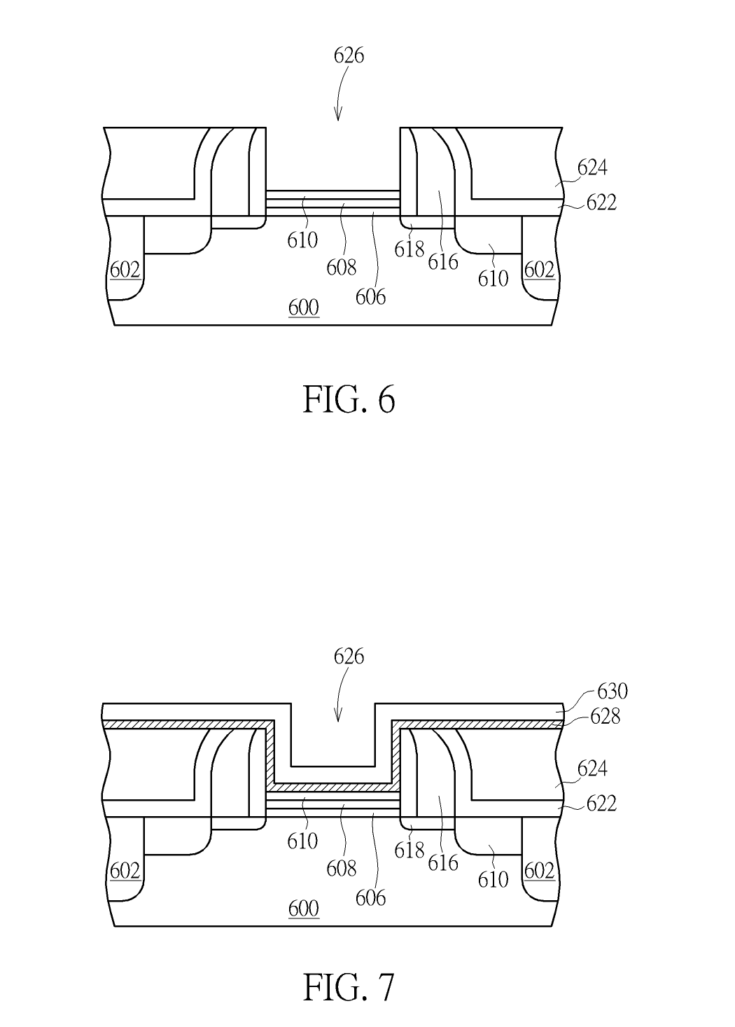

As shown in FIG. 6, the sacrifice gate 612 is removed, for example, by a wet etching process, a dry etching process, or their combination. In one embodiment, if the sacrifice gate 612 is comprised of poly-silicon, it can be removed away by a wet etching process with NH₄OH as an etchant. The etching process is carried out until completely removing the sacrifice gate 612 and stops on the etching stop layer 610. A trench 626 is therefore formed.

Next, as shown in FIG. 7, after the removing process, the substrate 600 is transferred to a multi-chamber deposition apparatus capable of carrying out different deposition processes, such as the deposition apparatus 1000 in FIG. 1. The following steps will be described in corporation with the deposition apparatus 1000 in FIG. 1, but it is understood that the method can also be carried out by other deposition apparatus. As shown in FIG. 1 and FIG. 7, after loaded to the deposition apparatus 1000, the substrate 600 is first placed in the loadlock chambers 104A to degas thereto maintain an ultrahigh vacuum environment. Next, the wafer with the substrate 600 is transferred to a deposition chamber, for example, the processing chamber 102A. Here, as shown in FIG. 7, a first deposition process is performed to form a bottom barrier layer 628 conformally on the substrate 600, covering a surface of the ILD layer 624 and a surface of the trench 626. In one embodiment, the bottom barrier layer 628 is comprised of Ti, TiN, Ta, TaN, Ti/TiN, Ta/TaN or their combination. The bottom barrier layer 628 can be made of the same material or different material from that of the etching stop layer 610. For example, the bottom barrier layer 628 is TaN and the etching stop layer 610 is TiN. The bottom barrier layer 628 is about 20 angstroms. Next, the wafer with the substrate 600 is transferred to another chamber such as the processing chamber 102F. A work function metal (WFM) layer 630 is formed conformally on the bottom barrier layer 628 wherein the trench 626 is not completely filled with the WFM layer 630. The WFM layer 630 serves as a work function metal required by a transistor. In one preferred embodiment, the WFM layer 630 is an N-type WFM layer and includes titanium aluminides (TiAl), aluminum zirconium (ZrAl), aluminum tungsten (WAl), aluminum tantalum (TaAl) or aluminum hafnium (HfAl), but should not be limited thereto. More preferably, the WFM layer 630 is TiAl and a thickness thereof is about 100 angstroms.

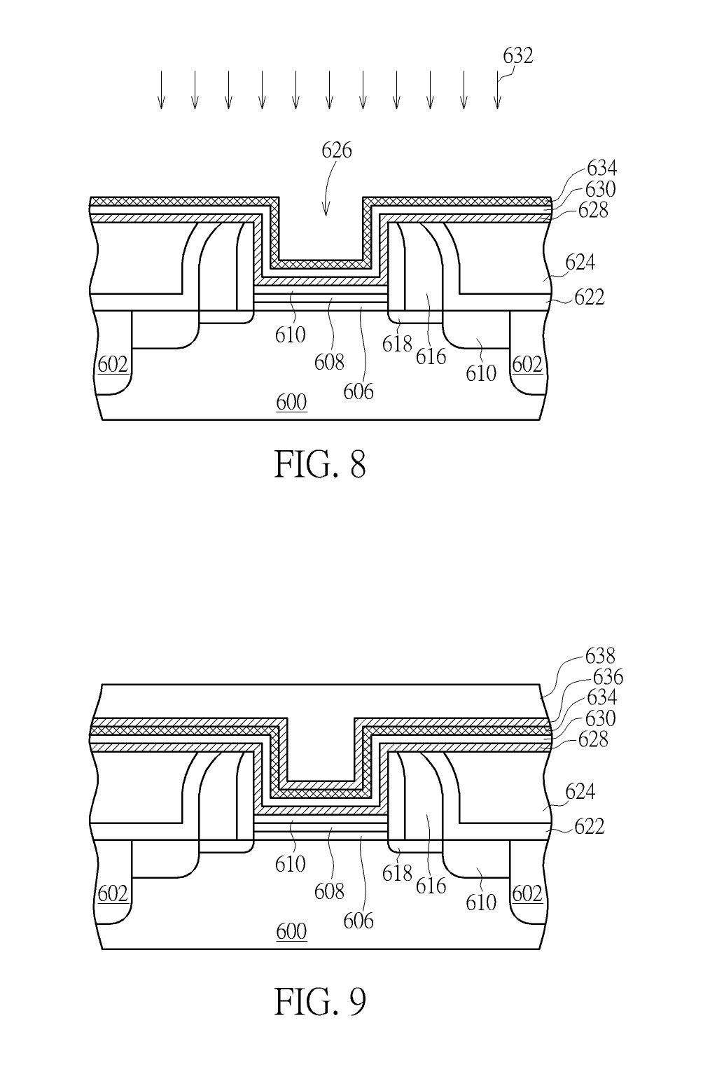

Next, as shown in FIG. 8 and FIG. 1, the substrate 600 is transferred to another chamber in the same deposition apparatus, for example, to the temporary chamber 108A of the deposition apparatus 1000. In this chamber, as shown in FIG. 8, an oxidation process 632 is performed to oxidize the WFM layer 630 (TiAl for example) and an upper part of the WFM layer 630 becomes an oxidized WFM layer 634 (TiAlO for example). In one embodiment, the oxidation process includes supplying a gas containing oxygen such as O₂, O₃, H₂O, N₂O, NO₂ or their combinations. The gas can be supplied by the gas source 406 in FIG. 2, and a flow thereof is between 20 and 4000 sccm. In another embodiment, the gas can further include N₂, He or Ar. As noted, the oxidation process is performed under an ultrahigh vacuum environment, such as 10⁻³ and 10⁻⁶ torr and under a room temperature (about 20 to 50 Celsius degrees). In one embodiment, if the temporary chamber 108A is equipped with a heater, the oxidation process can be performed with an annealing process (about 300 to 500 Celsius degrees), which can facilitate the oxidation process. In another embodiment, the substrate 600 can also be transferred to other chambers in the deposition apparatus 1000, including the processing chambers 102B-102E, the temporary chambers 108B or the service chambers 112A, 112B, depending on the design of the procedure.

After forming the oxidized WFM layer 634, the wafer with the substrate 600 is transferred to the next chamber, such as the processing chamber 102B in FIG. 1. As shown in FIG. 9, a top barrier layer 636 is deposited conformally on the oxidized WFM layer 634. In one embodiment, the top barrier layer 636 is comprised of Ti, TiN, Ta, TaN, Ti/TiN, Ta/TaN or their combination, and a thickness thereof is about 40 angstroms. Thereafter, the wafer with the substrate 600 is transferred to the next processing chamber 102C for example, and a conductive layer 638 is deposited on the top barrier layer 636 to completely fill the trench 626. The conductive layer 638 can be made of any low resistance material such as Al, Ti, Ta, W, Nb, Mo, TiN, TiC, TaN, Ti/W or Ti/TiN, but is not limited thereto.

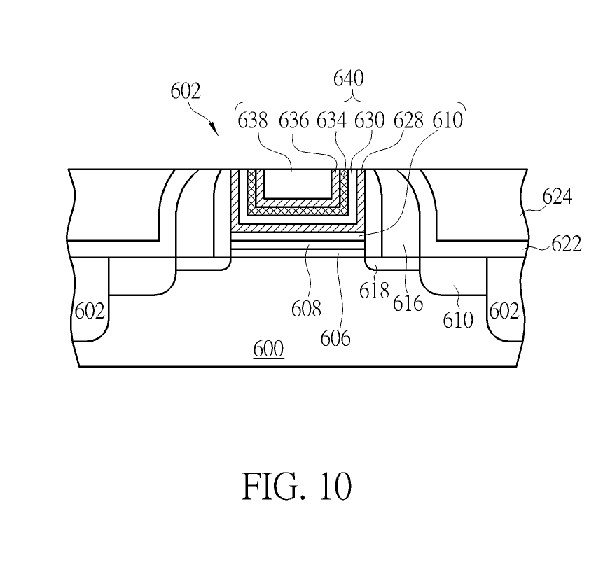

After the above-mentioned deposition processes, the wafer with the substrate 600 is transferred out from the deposition apparatus 1000, and as shown in FIG. 10, a planarization process is performed to remove the conductive layer 638, the top barrier layer 636, the oxidized WFM layer 634, the WFM layer 630 and the bottom barrier layer 628 outside the trench 626. Thus, the etching stop layer 610, the bottom barrier layer 628, the WFM layer 630, the oxidized WFM layer 634, and the conductive layer 638 in the trench 626 together form a metal gate 640 of the transistor 602. Because the oxidized WFM layer 634 can improve the electrical property of the WFM layer 630, a good performance of the metal gate 640 can therefore be obtained. It is understood that in another embodiment, besides the metal layers shown above, other metal layer that can improve the performance of the metal gate 640 can also be included therein.

The above embodiment shows forming the high-k gate dielectric layer at first (namely, the “high-k first” process). However, those skilled in the art can realize that, in the present invention, it is also available to form the high-k gate dielectric layer after removing the sacrifice gate (namely, the “high-k last” process). In this embodiment, the etching stop layer 610 can be omitted.

As described above, in one embodiment, the steps of deposition the metal layers of the metal gate is preferably carried out in the same deposition apparatus 1000 and under an ultra-high vacuum environment. No air-broken process is used during forming the WFM layer and forming the oxidized WFM layer. In conventional procedure, these deposition steps usually require two deposition apparatus, one for forming the bottom barrier layer and the WFM layer and the other for forming the top barrier layer and the conductive layer. In some cases, a small part of the WFM would be oxidized to form the oxidized WFM layer when the wafer is transferred from one deposition apparatus to another deposition apparatus, and an air broken step occurs. However, since the oxidized WFM layer is formed outside the deposition apparatus, it is under a room temperature and an atmosphere pressure, taking more than 2-4 hours to completely the oxidation process. In comparison, the present invention eliminates the needs to transfer the wafer out from the apparatus and one only deposition apparatus is needed to conduct all the metal gate deposition processes (in-situ deposition and oxidation). It is particularly advantageous in the present invention that the oxidation process can be performed with an annealing process, the overall throughout can therefore be upgraded.

Those skilled in the art will readily observe that numerous modifications and alterations of the device and method may be made while retaining the teachings of the invention. Accordingly, the above disclosure should be construed as limited only by the metes and bounds of the appended claims.

1. A method of forming a metal gate structure, comprising:
providing a substrate and a dielectric layer on the substrate, wherein a trench is disposed in the dielectric layer;
forming a work function metal (WFM) layer in the trench;
performing an oxidation process under a vacuum condition to oxidize a part of the WFM layer to form an oxidized WFM layer, wherein the steps of forming the WFM layer and the oxidation process are carried out in the same deposition apparatus, the step of forming the WFM layer is performed in a first chamber, and the oxidation process is performed in a second chamber, wherein the first chamber and the second chamber are operated under the identical vacuum condition, and no air-broken process is used during forming the WFM layer and forming the oxidized WFM layer; and
forming a conductive layer on the oxidized WFM layer to complete fill the trench.

2. (canceled)

3. (canceled)

4. The method of forming a metal gate structure according to claim 1, wherein the second chamber is a temporary chamber.

5. The method of forming a metal gate structure according to claim 1, wherein the second chamber is a service chamber or a processing chamber.

6. The method of forming a metal gate structure according to claim 1, wherein the oxidation process is performed by supplying a gas containing O₂, O₃, H₂O, H₂O₂, N₂O or NO₂.

7. The method of forming a metal gate structure according to claim 6, wherein a flow of the gas is between 20 and 4000 sccm.

8. The method of forming a metal gate structure according to claim 6, wherein the gas further comprises N₂, He or Ar.

9. The method of forming a metal gate structure according to claim 1, wherein the oxidation process is performed under a temperature between 300 and 500 Celsius degrees.

10. The method of forming a metal gate structure according to claim 1, wherein the oxidation process is performed under a room temperature.

11. The method of forming a metal gate structure according to claim 1, wherein the vacuum condition is between 10⁻³ and 10⁻⁶ ton.

12. The method of forming a metal gate structure according to claim 1, wherein the WFM layer is an N-type WFM layer.

13. The method of forming a metal gate structure according to claim 12, wherein the WFM comprises TiAl, ZrAl, WAl, TaAl or HfAl.

14. The method of forming a metal gate structure according to claim 12, wherein the WFM comprises TiAl and the oxidized WFM comprises TiAlO.

15. The method of forming a metal gate structure according to claim 1, before forming the WFM layer, further comprising forming a bottom barrier layer in the trench.

16. The method of forming a metal gate structure according to claim 15, wherein the bottom barrier layer comprises Ti, TiN, Ta, TaN, Ti/TiN or Ta/TaN.

17. The method of forming a metal gate structure according to claim 15, before forming the bottom barrier layer, further comprising forming an etching stop layer in the trench.

18. The method of forming a metal gate structure according to claim 17, wherein the etching stop layer comprises Ti, TiN, Ta, TaN, Ti/TiN or Ta/TaN.

19. The method of forming a metal gate structure according to claim 1, further comprising forming a top barrier layer between the oxidized WFM layer and the conductive layer.

20. The method of forming a metal gate structure according to claim 19, wherein the top barrier layer comprises Ti, TiN, Ta, TaN, Ti/TiN or Ta/TaN.
